(19) United States
(12) Patent Application Publication
(10) Pub. No.: US 2026/0206580 A1
(43) Pub. Date: Jul. 16, 2026

(54) THERMAL EXPANSION-CONTROLLED PACKAGING SUBSTRATE

(71) Applicant: INTERNATIONAL BUSINESS MACHINES CORPORATION, ARMONK, NY (US)

(72) Inventors: John Knickerbocker, Monroe, NY (US); Keiji Matsumoto, Yokohama-shi (JP); Mukta Ghate Farooq, Hopewell Junction, NY (US); Todd Edward Takken, Brewster, NY (US); John W. Golz, Hopewell Junction, NY (US)

(21) Appl. No.: 19/023,154

(22) Filed: Jan. 15, 2025

(51) Int. Cl. H01L 23/367; H01L 21/48; H01L 21/50; H01L 23/14; H01L 23/373; H01L 25/07

(52) U.S. Cl. CPC H10W 40/22; H10W 70/05; H10W 90/00; H10W 95/00; H10W 40/253; H10W 40/254; H10W 70/695; H10W 90/288; H10W 90/297

(57) ABSTRACT

A semiconductor device includes a substrate including one or more layers of pitch line and space (L/S) build-up and a core, a chiplet over the substrate, and a processing unit over the substrate.

### BACKGROUND

### Technical Field

The present disclosure generally relates to semiconductors, and more particularly, to semiconductors with thermally expansion-controlled packaging substrate structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a substrate including one or more layers of fine line and space (L/S) build-up and a core, a chiplet over the substrate, and a processing unit over the substrate.

In one embodiment, the semiconductor device includes a heat spreader extending over top of the processing unit and the chiplet, and the heat spreader is connected to the substrate on opposite ends of the substrate.

In one embodiment, the substrate is an organic substrate, and the core includes a low coefficient of thermal expansion (CTE) material.

In one embodiment, the semiconductor device includes at least one of: one or more through via holes in the core or one or more through silicon vias in the core.

In one embodiment, the substrate is a thermally conductive substrate.

In one embodiment, the core is a dielectric core including at least one of: Aluminum nitride (AlN), Sapphire, Beryllium oxide (BeO), Silicon nitride (S3N4), Gallium nitride (GaN), Boron nitride (BN), or diamond.

In one embodiment, the core and the one or more layers of fine line and space (L/S) build-up are connected via at least one of: an adhesion layer, a liner, or metal vias.

In one embodiment, the semiconductor device includes one or more solder resists between the substrate and the chiplet and the processing unit, one or more controlled collapse chip connections (C4) between the substrate and the chiplet and the processing unit, and a back end of line (BEOL) between the substrate and the chiplet and the processing unit.

In one embodiment, the core is located between two alternating layers of the one or more layers of fine L/S build-up.

In one embodiment, the core includes at least two core layers, and the one or more layers of fine L/S build-up are located between the at least two core layers.

According to an embodiment, a method for fabrication of a semiconductor device includes forming a substrate including forming one or more layers of fine pitch line and space (L/S) build-up; and forming a core, forming a chiplet over the substrate; and forming a processing unit over the substrate.

In one embodiment, the method includes forming a heat spreader extending over top of the processing unit and the chiplet, and connecting the heat spreader to the substrate on opposite ends of the substrate.

In one embodiment, the method includes forming at least one of: one or more through via holes in the core or one or more through silicon vias in the core.

In one embodiment, the method includes connecting the core and the one or more layers of fine L/S build-up via at least one of: an adhesion layer, a liner, or metal vias.

In one embodiment, the method includes forming one or more solder resists between the substrate and the chiplet and the processing unit, forming one or more controlled collapse chip connections (C4) between the substrate and the chiplet and the processing unit, and forming a back end of line (BEOL) between the substrate and the chiplet and the processing unit.

In one embodiment, the method includes forming the core between two alternating layers of the one or more layers of fine L/S build-up.

In one embodiment, the core includes at least two core layers, and wherein the one or more layers of fine pitch L/S build-up are formed between the at least two core layers.

According to an embodiment, a semiconductor device includes a substrate having one or more layers of fine line and space (L/S) build-up and a core, a chiplet over the substrate, and a heat spreader extending over top of the chiplet. The heat spreader is connected to the substrate on opposite ends of the substrate.

In one embodiment, the substrate is an organic substrate, and the core includes a low coefficient of thermal expansion (CTE) material.

In one embodiment, the substrate is a thermally conductive substrate, the core is a dielectric core, and the dielectric core includes at least one of: AlN, Sapphire, BeO, S3N4, or diamond.

In one embodiment, the core and the one or more layers of fine L/S build-up are connected via at least one of: an adhesion layer, a liner, or metal vias.

In one embodiment, the semiconductor device includes one or more solder resists between the substrate and the chiplet, one or more controlled collapse chip connections (C4) between the substrate and the chiplet, and a back end of line (BEOL) between the substrate and the chiplet.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a conventional packaged semiconductor.

FIG. 2 illustrates a semiconductor device, in accordance with some embodiments.

FIG. 3 illustrates an augmented view of the substrate connected to the chiplet, in accordance with some embodiments.

FIGS. 4A-4F illustrate various configurations of the substrate of a semiconductor device, in accordance with some embodiments.

FIG. 5 illustrates a top view of the semiconductor device, in accordance with some embodiments.

FIG. 6 illustrates a substrate cooling in a semiconductor device, in accordance with some embodiments.

FIG. 7 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

According to an embodiment, a semiconductor device includes a substrate including one or more layers of pitch line and space (L/S) build-up and a core, a chiplet over the substrate, and a processing unit over the substrate. Thus, the semiconductor device offers a controlled CTE with fine L/S and high thermal conductivity substrate.

In one embodiment, the semiconductor device includes a heat spreader extending over top of the processing unit and the chiplet, and the heat spreader is connected to the substrate on opposite ends of the substrate. The heat spreader can remove the heat from the chiplets and the processing unit to the substrate.

In one embodiment, the substrate is an organic substrate, and the core includes a low coefficient of thermal expansion (CTE) material. Thus, the CTE can be controlled.

In one embodiment, the semiconductor device includes at least one of: one or more through via holes in the core or one or more through silicon vias in the core. Thus, the heat can be dissipated via the through silicon vias in the core.

In one embodiment, the substrate is a thermally conductive substrate. Thus, the substrate can facilitate the heat dissipation.

In one embodiment, the core is a dielectric core including at least one of: AlN, Sapphire, BeO, S3N4, or diamond. Various types of dielectrics can improve device performance.

In one embodiment, the core and the one or more layers of fine L/S build-up are connected via at least one of: an adhesion layer, a liner, or metal vias. Thus, the fine L/S build-up-to-core connection is enhanced.

In one embodiment, the semiconductor device includes one or more solder resists between the substrate and the chiplet and the processing unit, one or more controlled collapse chip connections (C4) between the substrate and the chiplet and the processing unit, and a back end of line (BEOL) between the substrate and the chiplet and the processing unit. The resists, C4 and BEOL facilitate the connectivity within the device.

In one embodiment, the core is located between two alternating layers of the one or more layers of fine L/S build-up. The core can be sandwiched within fine L/S build-up layers in a configuration.

In one embodiment, the core includes at least two core layers, and the one or more layers of fine L/S build-up are located between the at least two core layers. The core can be divided into two portions and the fine L/S build-up can be sandwiched by the core portions in another configuration.

According to an embodiment, a method for fabrication of a semiconductor device includes forming a substrate including forming one or more layers of pitch line and space (L/S) build-up, and forming a core, forming a chiplet over the substrate; and forming a processing unit over the substrate. Thus, the semiconductor device offers a controlled CTE with fine L/S build-up or wiring and high thermal conductivity substrate.

In one embodiment, the method includes forming a heat spreader extending over top of the processing unit and the chiplet, and connecting the heat spreader to the substrate on opposite ends of the substrate. The heat spreader can remove the heat from the chiplets and the processing unit to the substrate.

In one embodiment, the method includes forming at least one of: one or more through via holes in the core or one or more through silicon vias in the core. Thus, the heat can be dissipated via the through silicon vias in the core.

In one embodiment, the method includes connecting the core and the one or more layers of fine L/S build-up via at least one of: an adhesion layer, a liner, or metal vias. Thus, the S/L-to-core connection is enhanced.

In one embodiment, the method includes forming one or more solder resists between the substrate and the chiplet and the processing unit, forming one or more controlled collapse chip connections (C4) between the substrate and the chiplet and the processing unit, and forming a back end of line (BEOL) between the substrate and the chiplet and the processing unit. The resists, C4 and BEOL facilitate the connectivity within the device.

In one embodiment, the method includes forming the core between two alternating layers of the one or more layers of fine L/S build-up. The core can be sandwiched within L/S build-up layers in a configuration.

In one embodiment, the core includes at least two core layers, and wherein the one or more layers of L/S build-up are formed between the at least two core layers. The core can be divided into two portions and the L/S build-up can be sandwiched by the core portions in another configuration.

According to an embodiment, a semiconductor device includes a substrate having one or more layers of pitch line and space (L/S) build-up and a core, a chiplet over the substrate, and a heat spreader extending over top of the chiplet. The heat spreader is connected to the substrate on opposite ends of the substrate. Thus, the semiconductor device offers a controlled CTE with fine L/S build-up or wiring and high thermal conductivity substrate.

In one embodiment, the substrate is an organic substrate, and the core includes a low coefficient of thermal expansion (CTE) material. Thus, the CTE can be controlled.

In one embodiment, the substrate is a thermally conductive substrate, the core is a dielectric core, and the dielectric core includes at least one of: AlN, Sapphire, BeO, S3N4, or diamond. Various types of dielectrics can improve device performance.

In one embodiment, the core and the one or more layers of fine L/S build-up are connected via at least one of: an adhesion layer, a liner, or metal vias. Thus, the fine L/S build-up-to-core connection is enhanced.

In one embodiment, the semiconductor device includes one or more solder resists between the substrate and the chiplet, one or more controlled collapse chip connections (C4) between the substrate and the chiplet, and a back end of line (BEOL) between the substrate and the chiplet. The resists, C4 and BEOL facilitate the connectivity within the device.

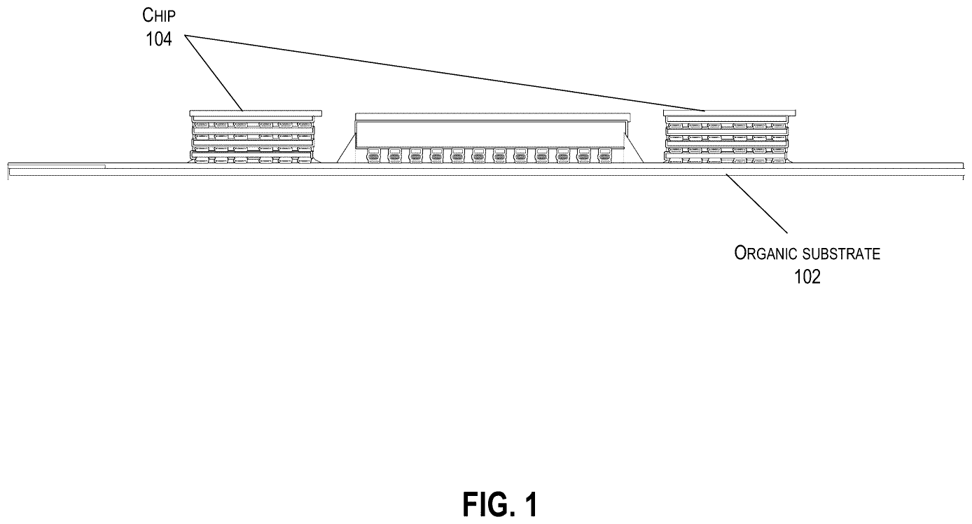

Low Temperature Co-fired Ceramic (LTCC) technology is widely utilized in the electronics industry for creating multilayer ceramic substrates essential for various applications, including telecommunications, automotive systems, and consumer electronics. Despite its advantages, LTCC faces significant challenges that can affect its performance and manufacturability. Two primary issues are the limited precision in through-via-hole placement and the high coefficient of thermal expansion (CTE) resulting from the substantial use of copper (Cu) in the process. FIG. 1 illustrates a conventional packaged semiconductor. One of the primary challenges with LTCC substrates is the limited accuracy in the placement of through-via holes. Through-vias are essential for establishing vertical electrical connections between different layers of the substrate and the semiconductor chip. In LTCC manufacturing, achieving high precision in via location is difficult due to factors such as material shrinkage during the firing process and limitations in the fabrication techniques. This lack of precision means that LTCC substrates are not suitable for fine pitch line and space (L/S) applications. Fine pitch L/S refers to the ability to create very narrow conductive lines and spaces between them, which is crucial for high-density interconnects in modern semiconductor devices.

Fine pitch L/S is mandatory for current and future semiconductor technology nodes, particularly at 7 nanometers (nm) and below. As the industry progresses towards smaller technology nodes, the demand for increased integration density requires more precise and finer interconnects. The inability of LTCC substrates to support such fine features limits their applicability in cutting-edge semiconductor technologies. Without the capability to fabricate fine pitch L/S, LTCC substrates cannot meet the electrical performance and miniaturization requirements of advanced devices.

Additionally, thermal management has become a critical aspect of semiconductor design, especially in three-dimensional integration (3Di) and backside power delivery networks (BSPDN). In these architectures, heat generation is significant due to the high density of active components stacked vertically or integrated on the backside of the chip. Thermal management through the substrate emerges as a viable solution to dissipate this heat effectively. For such thermal pathways to be efficient, the substrate material must possess high thermal conductivity to facilitate rapid heat transfer away from the active regions. In the context of LTCC, while ceramics generally have better thermal conductivity than organic materials, standard LTCC substrates may still fall short of the thermal performance required for 3Di and BSPDN applications. Enhancing the thermal conductivity of LTCC substrates often involves incorporating materials with higher thermal conductivities, such as aluminum nitride or integrating metal fillers. However, these modifications can introduce additional manufacturing complexities, increase costs, and may impact other substrate properties like mechanical strength or electrical insulation.

Another significant challenge associated with LTCC is the high coefficient of thermal expansion (CTE), primarily due to the large volume of copper used in the conductive layers. The coefficient of thermal expansion (CTE) mismatch between an organic substrate 102 and a semiconductor chip 104 remains a significant challenge in the assembly and reliability of today's semiconductor packages. Organic substrates typically have a CTE of approximately 17 parts per million per degree Celsius (ppm/° C.), whereas silicon chips have a much lower CTE of about 3 ppm/° C. This disparity leads to mechanical stresses during thermal cycling, which can cause delamination, cracking, and failure of solder joints. These mechanical failures compromise the structural integrity and reliability of the semiconductor device, affecting its performance and lifespan.

CTE is a material property that describes how much a material expands or contracts with temperature changes. In LTCC substrates, the high CTE resulting from copper can lead to several adverse effects. Electronic devices typically incorporate multiple materials, each with its own CTE. A high CTE in LTCC can create a thermal mismatch between the ceramic substrate and other components such as semiconductor dies, metal leads, or insulating layers. This mismatch induces mechanical stresses during thermal cycling, where the device undergoes temperature variations during operation or environmental changes. These stresses can cause mechanical deformation, cracking, or delamination of the ceramic layers, which not only affects the structural integrity of the substrate but also disrupts electrical pathways, leading to device failure. Over time, repeated expansion and contraction due to temperature changes can degrade the material properties of the LTCC substrate and its metallization. This degradation manifests as increased electrical resistance, intermittent connections, or complete electrical failures, particularly in applications subjected to harsh operating conditions. Additionally, high CTE can impact the overall performance of the electronic device by causing variations in signal integrity, increased noise levels, and reduced precision in high-frequency applications. Even minor mechanical distortions can have significant impacts on the performance and reliability of such devices.

Addressing these challenges is an objective of the disclosed semiconductor device which enhances the viability and performance of LTCC technology and improves the precision of through-via-hole placement. Improving the precision of through-via-hole placement requires advancements in manufacturing techniques, such as better layer registration methods and more accurate lithography processes. Enhancing alignment accuracy during the lamination and firing stages can help achieve finer L/S configurations, thereby supporting higher-density interconnects and enabling greater miniaturization of electronic components. To mitigate the issue of high CTE, the material composition is optimized, which can involve incorporating materials with lower thermal expansion coefficients or reducing the volume of copper used without compromising the electrical performance of the conductive layers. By balancing the CTE through material innovation, it is possible to reduce (e.g., minimize) thermal mismatch and reduce the mechanical stresses that lead to device degradation. Additionally, developing advanced fabrication technologies that allow for more controlled deposition and distribution of copper can help manage the CTE more effectively, enhancing the overall reliability and longevity of LTCC-based electronic systems.

The disclosed semiconductor device incorporates an advanced thermal management system designed to efficiently dissipate heat generated by high-temperature areas on the chip, such as integrated circuits and other critical components. The system establishes multiple thermal pathways that direct heat away from these hot spots to maintain improved (e.g., optimal) operating temperatures and ensure the device's performance and longevity.

At the core of the thermal management strategy is the integration of various thermal conductors that facilitate heat transfer from the chip to larger heat dissipation structures. These thermal conductors include silicon (Si) layers, through-silicon vias (TSVs), copper (Cu) hybrid bonds, solder connections, and specialized pillars. Each of these components plays a distinct role in creating a comprehensive network for effective heat spreading and removal.

Silicon layers act as foundational thermal pathways, leveraging the inherent thermal conductivity of silicon to distribute heat evenly across the substrate. Through-silicon vias provide vertical thermal channels that penetrate the silicon substrate, allowing heat to be efficiently transferred from the active regions of the chip to external heat spreaders or sinks. Copper hybrid bonds further enhance thermal conductivity by offering highly efficient metal pathways that bridge different layers of the semiconductor package, ensuring reduced (e.g., minimal) thermal resistance.

Solder connections and pillars serve as robust mechanical and thermal interfaces that secure the semiconductor die to the package while simultaneously facilitating heat transfer. These components are strategically placed to optimize thermal conduction paths, ensuring that heat is effectively directed towards designated heat dissipation areas. The combination of these thermal conductors creates a multidimensional network that improves (e.g., maximizes) heat spreading across the package, reducing the likelihood of localized overheating.

Once heat is conducted away from the chip through these internal pathways, it is directed to the package's exterior through vias embedded within the package itself. These vias channel the heat to various locations, including the top, center core, and bottom of the package, or a combination of these areas, depending on the specific design and thermal requirements of the device. This strategic placement ensures that heat is distributed across the package in a manner that prevents thermal bottlenecks and promotes uniform heat dissipation.

To further enhance heat removal, the system utilizes thermal interface materials (TIM) and metal seals that interface with external heat sinks or heat spreaders. TIMs, such as thermal grease or phase-change materials, are applied between the thermal conductors and the heat sinks to improve thermal contact and reduce thermal resistance. Metal seals provide additional pathways for heat to be conducted away from the package, ensuring that heat is efficiently transferred to the external cooling elements. The heat sinks or heat spreaders themselves are designed to improve (e.g., maximize) surface area and facilitate convective and conductive heat transfer to the surrounding environment. By effectively spreading the heat across a larger area, these components prevent the accumulation of excessive heat in any single region, thereby maintaining the semiconductor device within safe operating temperatures.

Accordingly, the teachings herein provide methods and systems of semiconductor devices with thermally expansion-controlled substrate structure. The techniques described herein may be implemented in a number of ways. Example implementations are provided below with reference to the following figures.

Example Semiconductor Device with Thermally Expansion-controlled substrate Structure

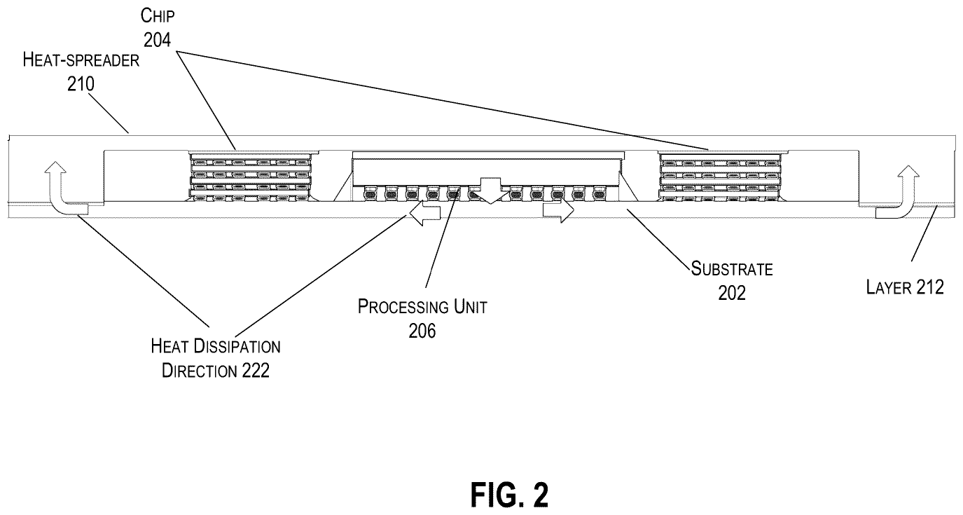

Reference now is made to FIG. 2, which is a simplified cross-section view of a of the semiconductor device. The semiconductor device includes a substrate 202 that includes one or more layers of pitch line and space (L/S) and a core. The substrate 202 serves as the foundational platform upon which other components of the semiconductor device are mounted. The pitch line and space (L/S) can be alternating conductive lines and insulating spaces that facilitate electrical interconnections within the substrate 202, enabling high-density routing essential for modern electronic circuits. The core within the substrate 202 provides structural integrity and can be composed of materials that contribute to the device's overall thermal and electrical performance.

In some embodiments, one or more chiplets 204 can be positioned over the substrate 202 A chiplet can be a smaller functional unit of a semiconductor chip, designed to perform specific tasks within the larger system. By integrating chiplets, the semiconductor device can achieve modularity and scalability, allowing for customized configurations tailored to various applications. Additionally, a processing unit 206, such as a CPU or a GPU, can be placed over the substrate 202, which handles the computational and control functions of the device. The processing unit 206 works in tandem with the one or more chiplets 204 to execute complex operations, manage data flow, and ensure efficient performance of the semiconductor device.

In some embodiments, the semiconductor device further includes a heat spreader 210. The heat spreader 210 extends over the top of both the processing unit 206 and the one or more chiplets 204, providing a pathway for heat dissipation generated during the device's operation. This component is connected to the substrate 202 at opposite ends, ensuring that heat is evenly distributed and effectively managed across the device. The heat spreader 210 maintains improved (e.g., optimal) operating temperatures, thereby enhancing the reliability and longevity of the semiconductor device by preventing overheating of critical components. The arrows indicate the heat dissipation direction 222 within the semiconductor device.

In some embodiments, the substrate 202 is an organic substrate, and the core includes a material with a low coefficient of thermal expansion (CTE). An organic substrate can include materials such as epoxy-based laminates, which offer flexibility and ease of manufacturing. The inclusion of a low CTE material in the core helps mitigate the thermal mismatch between the substrate and other components, such as silicon chips, which have a significantly lower CTE. This balance reduces mechanical stresses during thermal cycling, enhancing the assembly's reliability and preventing issues such as delamination or cracking that can compromise the device's structural integrity.

In some embodiments, the semiconductor device includes at least one through via hole in the core or one or more through silicon vias (TSVs) in the core. Through via holes and TSVs can be vertical electrical connections that traverse the core, enabling communication between different layers of the substrate and the mounted components. The vias establish robust electrical pathways, facilitates high-speed data transfer, and ensures efficient power distribution throughout the device. The presence of through via holes or TSVs enhances the device's performance by enabling dense interconnects and reducing signal latency. Adhesion layer, liner and metal vias are used in these via formation.

In some embodiments, the substrate 202 is characterized by high thermal conductivity. A high thermal conductivity substrate efficiently conducts heat away from active components, such as the one or more chiplets 204 and the processing unit 206, thereby aiding in effective thermal management. Materials with high thermal conductivity, such as certain ceramics or metal-based substrates, are employed to ensure rapid heat dissipation, preventing thermal buildup that can degrade performance or lead to thermal-induced failures. This property is particularly important in high-performance semiconductor devices where heat generation is substantial.

In some embodiments, the core is a dielectric core that includes materials such as aluminum nitride (AlN), sapphire, beryllium oxide (BeO), silicon nitride (S3N4), or diamond. A dielectric core is an insulating material that prevents electrical conduction while supporting the structural framework of the substrate. Materials such as AlN and diamond are chosen for their exceptional thermal conductivity and electrical insulation properties, which contribute to both thermal management and electrical performance. The selection of specific dielectric materials enhances the device's ability to handle high power densities and operate reliably under varying thermal conditions.

In some embodiments, a sealband with high thermal conductivity 212 is formed between the substrate 202 and the heat spreader 210. The sealband with high thermal conductivity 212 can be a specialized layer that surrounds and protects the chip while efficiently transferring heat away from it. This sealband can be made from materials that conduct heat well, such as certain metals or ceramic composites, allowing it to draw heat generated by components such as CPUs or GPUs and spread it across the substrate. By doing so, the sealband helps prevent overheating and maintains the device's performance and reliability. Additionally, the sealband with high thermal conductivity 212 provides mechanical protection against environmental factors and physical stresses, ensuring the integrity of the semiconductor package. This combination of thermal management and protection is crucial for high-performance and reliable electronic devices.

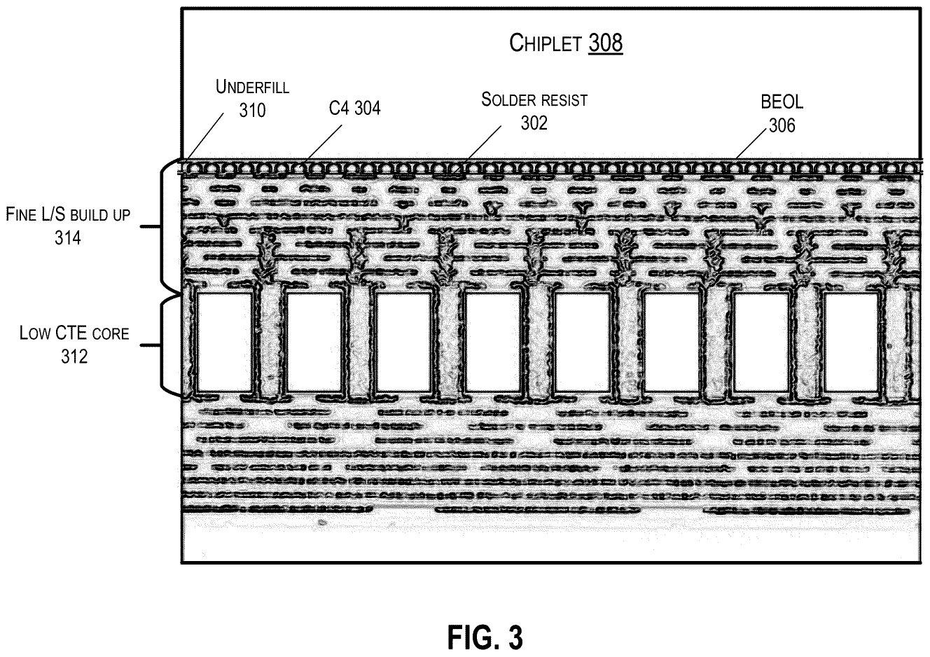

FIG. 3 illustrates an augmented view of the substrate connected to the chiplet, in accordance with some embodiments. In some embodiments, the semiconductor device incorporates one or more solder resists 302 between the substrate and the chiplet 308 and the processing unit. Solder resists are protective layers that prevent unwanted solder flow during the assembly process, ensuring precise placement and reliable connections between components. Additionally, the device includes controlled collapse chip connections, C4 304, between the substrate and the chiplet and the processing unit. C4 304 provides robust and uniform solder joints that enhance electrical and mechanical connectivity, contributing to the device's overall stability. A back end of line, BEOL 306, is also integrated between the substrate and the chiplet and the processing unit, which involves interconnects and surface finishes that complete the device's electrical pathways. The semiconductor device can further include underfill 310 which can mitigate mechanical stresses that arise due to differences in the CTE between the chip and the substrate, thereby preventing various forms of failure and ensuring the longevity of the electronic assembly. The substrate can include a core, e.g., low CTE core 312, and one or more layers of L/S, e.g., fine L/S buildup 314.

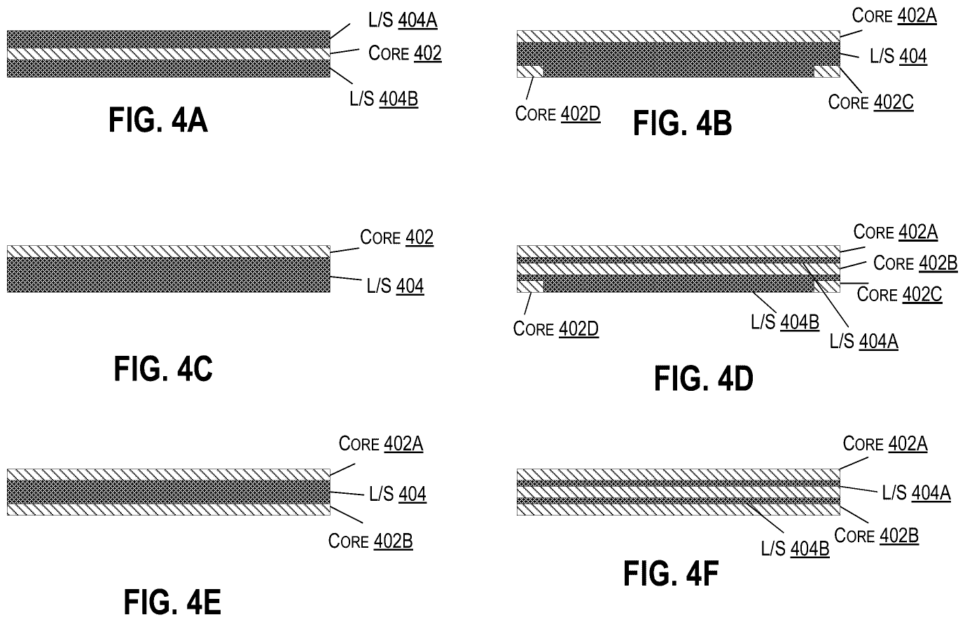

FIGS. 4A-4F illustrate various configurations of the substrate of a semiconductor device, in accordance with some embodiments. In some embodiments, the core 402 is situated between two alternating layers of the one or more layers of L/S 404. This configuration creates a sandwich structure where the core 402 provides mechanical support and thermal management, while the alternating layers of L/S 404 facilitate dense electrical interconnections. Placing the core 402 between multiple layers of L/S 404 enhances the device's ability to manage heat and maintain electrical performance across different layers, contributing to a compact and efficient design suitable for advanced semiconductor applications. The core can include more than one layers, such as layers 402A and 402B, and portions on the opposite sides of the substrate, such as portions 402C and 402D.

In some embodiments, the core 402 includes at least two core layers, e.g., 402A and 402B, and the one or more layers of L/S 404 are located between these core layers. A multi-layer core structure further improves the device's thermal and electrical performance by providing additional pathways for heat dissipation and electrical interconnects. The placement of L/S layers, e.g., 404A and 404B, between multiple core layers allows for greater flexibility in routing electrical signals and distributing heat, enabling the creation of highly integrated and high-performance semiconductor devices. This layered approach supports the development of complex, multi-functional devices that meet the demanding requirements of modern electronics.

In some embodiments, the substrate of the semiconductor device is constructed from a low coefficient of thermal expansion (CTE) core in conjunction with build-up layers including alternating line and space (S/L) patterns. The low CTE core is engineered to closely match the thermal expansion properties of the semiconductor chip, thereby reducing (e.g., minimizing) mechanical stresses that arise from temperature fluctuations during device operation. This matching of CTE values enhances the overall reliability and longevity of the semiconductor package by reducing the risk of delamination, cracking, and other thermal-induced failures.

The fabrication of through-via-holes within the substrate is achieved using techniques such as plasma processing, laser machining, or the integration of copper-based vias including through-dielectric vias (TDVs), through-silicon vias (TSVs), and through-carrier cias (TCVs). Plasma and laser methods offer control over the etching and drilling processes, enabling the creation of vias with high dimensional accuracy and smooth sidewalls. Alternatively, copper-based vias like TDVs, TSVs, and TCVs provide electrical connections while maintaining structural integrity. The enhanced accuracy in via placement made possible by these fabrication techniques is beneficial for achieving fine pitch line and space (L/S) configurations. Fine pitch L/S facilitates formation of high-density interconnects to accommodate the increasing complexity and miniaturization of electronic circuits. The ability to reliably produce vias with precise locations and small dimensions allows for the integration of densely packed S/L patterns, facilitating superior electrical performance and enabling the development of more compact and efficient semiconductor devices.

In some embodiments, the semiconductor device utilizes a core material that offers high thermal conductivity while also functioning as a dielectric. This dual functionality helps build up layers within the device using advanced techniques such as plasma processing, laser machining, or alternative methods. These processes support the formation of vias, which are vertical electrical connections that traverse the substrate. To facilitate reliable via formation, the core may incorporate adhesion layers or liners, as well as metal vias made from materials such as copper (Cu). These metal vias can include various types, including TDVs, TSVs, TCVs, or other alternatives. The selection of materials and the incorporation of electrical isolation, liners, seeds, and metal vias depend on the resistivity requirements of the specific application. This approach ensures that the thermal and electrical properties of the core are optimized for efficient heat dissipation and robust electrical connectivity.

In some embodiments, the substrate of the semiconductor device is engineered to provide a controlled coefficient of thermal expansion (CTE) ranging from approximately 1 part per million (ppm) to about 12 ppm per degree Celsius. This controlled CTE is crucial for reducing (e.g., minimizing) thermal mismatch between the substrate and other components, thereby enhancing the reliability and longevity of the device. Additionally, the substrate is designed to maintain controlled planarity, ensuring a flat and even surface for the subsequent layering and integration of various components. The substrate also serves as an electrical insulator while possessing high thermal conductivity, which is vital for effective heat management. Furthermore, the substrate supports fabrication processes at both the wafer and panel levels, allowing for scalable manufacturing and integration into different semiconductor packaging formats.

In some embodiments, the dielectric core within the substrate is composed of materials known for their thermal and electrical insulating properties. Examples of such dielectric materials include aluminum nitride (AlN), sapphire, beryllium oxide (BeO), silicon nitride (S3N4), and diamond. These materials are chosen for their ability to provide electrical insulation while facilitating efficient heat dissipation. Additionally, coatings such as Diamond-like carbon (DLC) or pure diamond, as well as materials such as silicon (Si), silicon carbide (SiC), silicon carbonitride (SiCN), aluminum (Al), copper (Cu), and stainless steel (SS), can be applied as alternative coatings to enhance the thermal conductivity and mechanical properties of the core. These coatings help protect the substrate and improve the overall thermal management capabilities of the semiconductor device.

In some embodiments, the substrate incorporates line and space (L/S) layers on either side of the core, functioning as high thermal conductivity layers. The L/S layers can include alternating conductive lines and insulating spaces that facilitate dense electrical interconnections within the substrate. By placing these high thermal conductivity layers on either side of the core, the device can effectively distribute heat generated by active components such as chiplets and processing units. This configuration not only enhances electrical performance by enabling high-density routing but also improves thermal dissipation, ensuring that heat is efficiently spread across the substrate and directed towards heat sinks or spreaders.

In some embodiments, the semiconductor device establishes comprehensive thermal pathways from high-temperature areas on the chip, such as integrated circuits, to heat spreaders or heat sinks. These thermal pathways are created using a combination of thermal conductors, including silicon (Si) layers, vias, copper hybrid bonds, solder connections, and pillars. These conductors facilitate the transfer and spreading of heat through the package, ensuring that it is effectively removed from critical components. Heat removal occurs through vias embedded within the package, directing heat to the top, center core, bottom, or a combination of these regions. Additionally, thermal conductors extend to seals, metal interfaces, or thermal interface materials (TIM) that connect to external heat sinks or spreaders. This intricate network of thermal pathways ensures efficient heat dissipation, maintaining improved (e.g., optimal) operating temperatures and enhancing the device's performance and reliability.

In some embodiments, the semiconductor device includes groups of TSVs, TDVs, or similar structures arranged in grouped areas designated for signal transmission. Grouping these vias in specific regions optimizes signal integrity and reduces electrical noise by reducing (minimizing) the distance between interconnected components. This arrangement is beneficial for high-speed signal transmission and high-frequency applications, where maintaining signal quality is paramount. By organizing TSVs or TDVs into dedicated signal areas, the device can achieve more efficient and reliable electrical performance, supporting the demands of advanced semiconductor technologies.

In some embodiments, the semiconductor device employs organic build-up materials such as photosensitive polyimide (PSPI) and build-up materials. These organic materials are used to create additional layers within the semiconductor package, providing insulation, structural support, and protection for underlying components. PSPI materials offer excellent patterning capabilities, allowing for precise formation of interconnects and vias, The use of these organic materials facilitates the fabrication of complex, multi-layered semiconductor devices with enhanced electrical and thermal properties.

In some embodiments, the semiconductor device's performance is influenced by the grain size of the materials used within the substrate and thermal conductors. Grain size can significantly impact the thermal conductivity of materials; smaller grain sizes typically enhance thermal conductivity by providing more grain boundaries that facilitate heat transfer. Conversely, larger grains can reduce thermal conductivity due to fewer boundaries and increased potential for thermal scattering. By carefully controlling the grain size during the fabrication process, the thermal conductivity of the substrate and its components can be optimized to improve heat dissipation and overall device performance. Adjusting grain size is a critical parameter in the design and manufacturing of high-performance semiconductor devices, enabling tailored thermal management solutions that meet specific application requirements.

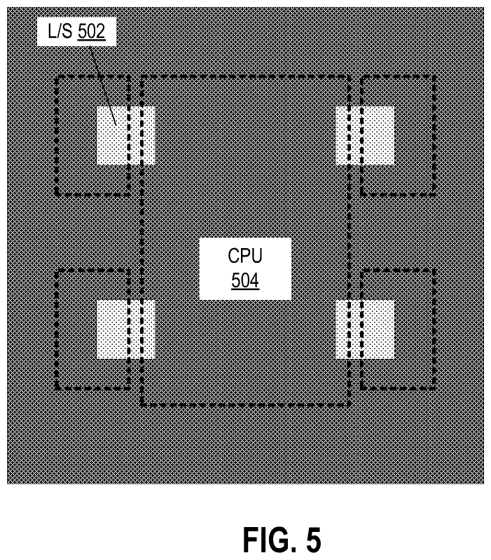

FIG. 5 illustrates a top view of the semiconductor device, in accordance with some embodiments. In some embodiments, high bandwidth (BW) chip-to-chip communication is achieved through the implementation of extremely fine line and space (L/S) wirings, e.g., L/S 502. High bandwidth can be the ability of a communication channel to transmit large amounts of data at high speeds, which is essential for modern semiconductor devices that demand rapid data transfer between multiple chips or components. Chip-to-chip communication involves the exchange of data signals directly between individual semiconductor chips within a system, bypassing traditional motherboard or backplane connections to reduce latency and increase overall system performance.

The realization of high bandwidth communication is intrinsically linked to the precision and density of the interconnecting wirings between chips. Extremely fine L/S wirings, which can be used as signal, can be used with small (e.g., minimal) dimensions, allowing for a higher number of interconnects per unit area. In some embodiments, the L/S wirings enable a greater density of interconnections, which directly contributes to increased data throughput. With more conductive lines packed into a given area, the communication channels between chips, e.g., CPU 504, can support multiple simultaneous data streams, thereby enhancing the overall bandwidth of the system. Further, the L/S wirings reduce the physical distance that electrical signals must travel between chips. Shorter signal paths result in lower signal latency and reduced propagation delay, which are crucial for maintaining high-speed data transfer rates. Additionally, shorter interconnects minimize the potential for signal degradation and electromagnetic interference (EMI), ensuring that data integrity is preserved even at high frequencies.

Moreover, the use of advanced fabrication techniques to achieve the L/S wirings allows for the integration of more complex and sophisticated communication protocols within the chip-to-chip interface. Techniques such as photolithography, electron beam lithography, and advanced etching processes are employed to create the precise geometries required for ultra-fine L/S patterns. These methods enable the production of wirings with sub-micron dimensions, which are necessary to meet the escalating demands of high-bandwidth applications. In some embodiments, the substrate or interposer that houses the fine L/S wirings is constructed using materials with superior electrical and thermal properties to support high-speed communication. Materials such as low-loss dielectrics, high-conductivity metals such as copper or silver, and advanced composite substrates are utilized to enhance signal transmission and heat dissipation. These materials help maintain the integrity of the high-frequency signals and prevent thermal hotspots that could otherwise impede performance.

Additionally, the design of the L/S wirings incorporates advanced signal integrity techniques to mitigate issues such as crosstalk, signal reflection, and impedance mismatches. Techniques such as differential signaling, controlled impedance lines, and shielding structures are integrated into the wiring layout to ensure that high-bandwidth signals remain clear and reliable. These design considerations are essential for maintaining high performance in densely packed interconnect environments. The implementation of such extremely fine L/S wirings also facilitates the development of multi-layer interconnect structures, where multiple conductive layers are stacked vertically to further increase the number of available communication pathways. This multi-layer approach allows for the parallel transmission of data, significantly boosting the overall bandwidth between chips. Advanced TSVs and micro-vias are employed to interconnect these layers, providing vertical electrical connections that complement the horizontal fine L/S patterns.

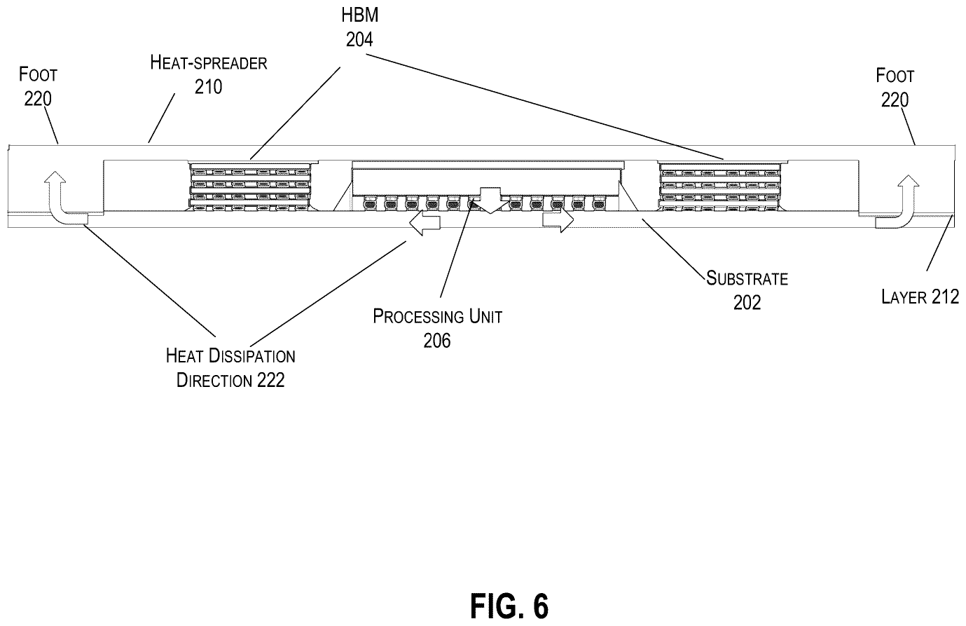

FIG. 6 illustrates a substrate cooling in a semiconductor device, in accordance with some embodiments. In some embodiments, the use of the substrate enables effective substrate cooling, which is essential for maintaining the improved (e.g., optimal) operating temperatures of high-performance semiconductor devices such as CPUs and GPUs. The substrate helps in thermal management by acting as a conduit for heat dissipation. When a CPU or GPU generates heat during operation, the thermal energy is conducted away from the active components and transferred to the substrate 202. The substrate, engineered with high thermal conductivity materials, facilitates the uniform spreading of heat across its surface. This widespread distribution of thermal energy prevents the formation of localized hot spots, which can lead to overheating and potential damage to the semiconductor components.

Once the heat is distributed throughout the substrate, it is further conducted to the foot 220 of a heat spreader 210. The heat spreader 210 is positioned to interface directly with the substrate, ensuring efficient transfer of thermal energy. The foot 220 of the heat spreader 210, which are in contact with the substrate, serve as points of thermal conduction where the spreader can effectively draw heat away from the substrate. From these contact points, the heat spreader 210 dissipates the thermal energy into the surrounding environment, often aided by additional cooling mechanisms such as heat sinks, fans, or liquid cooling systems.

This multi-step cooling process—heat conduction from the CPU/GPU to the substrate, spreading within the substrate, and transfer to the heat spreader—ensures that heat is managed efficiently across the entire semiconductor package. By leveraging the substrate's ability to conduct and distribute heat, the overall thermal performance of the device is enhanced, leading to improved reliability and longevity of the semiconductor components. Additionally, this approach allows for higher power densities and more compact device designs, as effective thermal management mitigates the risks associated with heat accumulation in densely packed electronic systems.

Furthermore, the integration of advanced materials and design techniques in the substrate enhances its thermal conductivity and mechanical stability. For instance, substrates may incorporate materials such as aluminum nitride (AlN), silicon carbide (SiC), or diamond, which possess superior thermal properties compared to traditional materials. These materials not only improve heat conduction but also contribute to the structural integrity of the substrate, ensuring that it can withstand the thermal and mechanical stresses encountered during device operation. The precise engineering of the substrate, including the layout of thermal pathways and the placement of thermal conductors, plays a crucial role in optimizing the overall cooling efficiency.

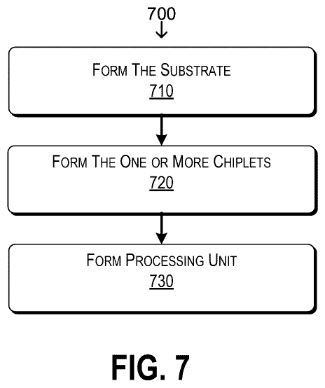

FIG. 7 illustrates a method 700 for forming the semiconductor device, in accordance with some embodiments. As shown by block 710, the substrate is formed.

As shown by block 720, the one or more chiplets are formed.

As shown by block 730, the processing unit is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate comprising one or more layers of fine line and space (L/S) build-up and a core;
a chiplet over the substrate; and
a processing unit over the substrate.

2. The semiconductor device of claim 1, further comprising a heat spreader, wherein:
the heat spreader extends over top of the processing unit and the chiplet; and
the heat spreader is connected to the substrate on opposite ends of the substrate.

3. The semiconductor device of claim 1, wherein:
the substrate is an organic substrate; and
the core includes a low coefficient of thermal expansion (CTE) material.

4. The semiconductor device of claim 1, further comprising at least one of: one or more through via holes in the core or one or more through silicon vias in the core.

5. The semiconductor device of claim 1, wherein the substrate is a high thermal conductivity substrate.

6. The semiconductor device of claim 1, wherein:
the core is a dielectric core; and
the dielectric core includes at least one of: AlN, Sapphire, BeO, S3N4, GaN, SiC, BN or diamond.

7. The semiconductor device of claim 1, wherein through via holes in the core has at least one of:
an adhesion layer, a liner, or metal vias.

8. The semiconductor device of claim 1, further comprising;
one or more solder resists between the substrate and the chiplet and the processing unit;
one or more controlled collapse chip connections (C4) between the substrate and the chiplet and the processing unit; and
a back end of line (BEOL) between the substrate and the chiplet and the processing unit.

9. The semiconductor device of claim 1, wherein the core is located between two alternating layers of the one or more layers of fine L/S build-up.

10. The semiconductor device of claim 1, wherein:
the core includes at least two core layers; and
the one or more layers of fine L/S build-up are located between the at least two core layers.

11. A method for fabrication of a semiconductor device, the method comprising:
forming a substrate comprising:
forming one or more layers of fine line and space (L/S) build-up; and
forming a core,
forming a chiplet over the substrate; and
forming a processing unit over the substrate.

12. The method of claim 11, further comprising:
forming a heat spreader extending over top of the processing unit and the chiplet; and
connecting the heat spreader to the substrate on opposite ends of the substrate.

13. The method of claim 11, further comprising forming at least one of: one or more through via holes in the core or one or more through silicon vias in the core.

14. The method of claim 11, further comprising through via holes in the core has at least one of: an adhesion layer, a liner, or metal vias.

15. The method of claim 11, further comprising;
forming one or more solder resists between the substrate and the chiplet and the processing unit;
forming one or more controlled collapse chip connections (C4) between the substrate and the chiplet and the processing unit; and
forming a back end of line (BEOL) between the substrate and the chiplet and the processing unit.

16. A semiconductor device, comprising:
a substrate comprising one or more layers of fine line and space (L/S) build-up and a core;
a chiplet over the substrate; and
a heat spreader,
wherein:
the heat spreader is extending over top of the chiplet; and
the heat spreader is connected to the substrate on opposite ends of the substrate.

17. The semiconductor device of claim 16, wherein:
the substrate is an organic substrate; and
the core includes a low coefficient of thermal expansion (CTE) material.

18. The semiconductor device of claim 16, wherein:
the substrate is a high thermal conductivity substrate;
the core is a dielectric core; and
the dielectric core includes at least one of: AlN, Sapphire, BeO, S3N4, GaN, SiC, BN or diamond.

19. The semiconductor device of claim 16, through via holes in the core has at least one of: an adhesion layer, a liner, or metal vias.

20. The semiconductor device of claim 16, further comprising;
one or more solder resists between the substrate and the chiplet;
one or more controlled collapse chip connections (C4) between the substrate and the chiplet; and
a back end of line (BEOL) between the substrate and the chiplet.
